(19) United States
(12) Patent Application Publication
(10) Pub. No.: US 2013/0270706 A1
(43) Pub. Date: Oct. 17, 2013

(54) SEMICONDUCTOR DEVICE

(71) Applicant: SUMITOMO ELECTRIC INDUSTRIES, LTD., Osaka-shi (JP)

(72) Inventors: Takahiro Sugimura, Osaka-shi (JP); Hiroshi Notsu, Osaka-shi (JP)

(73) Assignee: Sumitomo Electric Industries, Ltd., Osaka-shi (JP)

(21) Appl. No.: 13/852,819

(22) Filed: Mar. 28, 2013

Related U.S. Application Data
(60) Provisional application No. 61/622,656, filed on Apr. 11, 2012.

(30) Foreign Application Priority Data
Apr. 11, 2012 (JP) 2012-090043

(51) Int. Cl. H01L 23/498

(52) U.S. Cl. CPC H01L 23/49844
USPC 257/773

(57) ABSTRACT

A semiconductor device according to an embodiment includes: first and second semiconductor chips, each including a first electrode and a second electrode opposite to each other in a predetermined direction; a chip-mount substrate on which the first and second semiconductor chips are mounted; and a first wiring terminal to which the second electrodes of the first and second semiconductor chips are connected. The second semiconductor chip lies over the first semiconductor chip in the predetermined direction such that the second electrode of the first semiconductor chip and the second electrode of the second semiconductor chip face each other across the first wiring terminal, and the chip-mount substrate is bent such that the first electrode of the first semiconductor chip is connected to the first electrode of the second semiconductor chip.

### CROSS-REFERENCE TO RELATED APPLICATIONS

This application claims priority to Provisional Application Ser. No. 61/622,656, filed on Apr. 11, 2012 and claims the benefit of Japanese Patent Application No. 2012-090043, filed on Apr. 11, 2012, all of which are incorporated herein by reference in their entirety.

### BACKGROUND

1. Field

The present invention relates to a semiconductor device.

2. Related Background

Known as examples of semiconductor devices include those of a case type and those of a resin-sealed type (see “Technology for Evaluation of Failure Causes and Reliability Improvement of Wire Bonding Using Mainly Cu Wire” pp. 163 and 263, published by TECHNICAL INFORMATION INSTITUTE Co., Ltd, Jul. 29, 2011). These semiconductor devices each have a semiconductor chip mounted on a chip-mount substrate such as a die pad and connected to electrode terminals via wire.

### SUMMARY

A chip-mount substrate may include multiple semiconductor chips mounted thereon to achieve required performance of the semiconductor device. Nevertheless, it is difficult to mount a predetermined number of semiconductor chips on the chip-mount substrate enough to achieve required device performance, for example, in a smaller semiconductor device or a certain fixed size of chip-mount substrate according to a standard on devices.

An object of the present invention is to provide a semiconductor device in which multiple semiconductor chips can be efficiently disposed.

A semiconductor device according to an aspect of the present invention includes: first and second semiconductor chips, each including a first electrode and a second electrode opposite to each other in a predetermined direction; a chip-mount substrate on which the first and second semiconductor chips are mounted; and a first wiring terminal to which the second electrodes of the first and second semiconductor chips are connected. The second semiconductor chip lies over the first semiconductor chip in the predetermined direction such that the second electrode of the first semiconductor chip and the second electrode of the second semiconductor chip face each other across the first wiring terminal, and the chip-mount substrate is bent such that the first electrode of the first semiconductor chip is connected to the first electrode of the second semiconductor chip.

In this configuration, since the two semiconductor chips are stacked in the predetermined direction, the two semiconductor chips can be efficiently disposed compared with a lateral arrangement thereof.

According to one embodiment, each of the first and second semiconductor chips may be a transistor or a diode. In this case, transistors or diodes included in a semiconductor device can be efficiently disposed.

The semiconductor device according to one embodiment may further include a second wiring terminal. The first and second semiconductor chips of this configuration may be transistors. In this case, each of the first and second semiconductor chips further includes a third electrode at the side of the second electrode, and the second wiring terminal is connected to the third electrode of each of the first and second semiconductor chips.

In this configuration, the first to third electrodes can be used to drive each of the first and second semiconductor chips.

According to one embodiment, the first and second semiconductor chips may be transistors. In this case, each of the first and second semiconductor chips further includes a third electrode at the side of the first electrode, and the chip-mount substrate may be a wiring substrate including a wiring region for the first electrodes of the first and second semiconductor chips and a wiring region for the third electrodes of the first and second semiconductor chips.

In such a configuration, the first to third electrodes, which are transistors, can be supplied with predetermined power or signals using the wiring regions on the wiring substrate and the first wiring terminal.

The semiconductor device according to one embodiment may further include a die pad on which the chip-mount substrate is mounted.

In this case, the first and second semiconductor chips can be efficiently mounted on the die pad.

According to one embodiment, a chip-mount substrate may be a flexible printed wiring substrate.

In this case, the chip-mount substrate is readily bent.

According to one embodiment, the semiconductor device may include a plurality of laminates each having: the first semiconductor chip; the second semiconductor chip provided over the first semiconductor chip in the predetermined direction; and the wiring terminal provided between the second electrodes of the first and second semiconductor chips. In this case, the chip-mount substrate is bent such that the first electrodes of the first and second semiconductor chips in each laminate are connected with each other.

In this configuration, since the semiconductor chips configuring the multiple laminates are stacked in the predetermined direction, the semiconductor chips can be efficiently disposed compared with a lateral arrangement thereof.

According to one embodiment, a material of the first and second semiconductor chips may include a wide band gap semiconductor.

A wide band gap semiconductor has low production yields of a semiconductor chip and is expensive compared with silicon (Si). As a result, one large semiconductor chip produced with a wide band gap semiconductor similar to silicon would cause lowered production yields and increased manufacturing costs. For this reason, multiple small semiconductor chips are produced with a wide band gap semiconductor and are mounted on a chip-mount substrate, instead of one large semiconductor chip.

The configuration of a semiconductor device in which a second semiconductor chip lies over a first semiconductor chip in a predetermined direction achieves efficient disposition of the first and second semiconductor chips. Thus, such a configuration can be efficient in the case of first and second semiconductor chips made of a wide band gap semiconductor.

As mentioned above, a semiconductor device in which multiple semiconductor chips can be efficiently disposed can be provided.

### BRIEF DESCRIPTION OF THE DRAWINGS

FIG. 1 is a schematic plan view illustrating a semiconductor device according to a first embodiment.

FIG. 2 is a side view of a chip unit illustrated in FIG. 1.

FIG. 3A illustrates a step of manufacturing the chip unit illustrated in FIG. 2.

FIG. 3B illustrates the step subsequent to that in FIG. 3A.

FIG. 4 is a schematic plan view illustrating a semiconductor device according to a second embodiment.

FIG. 5 is a perspective view of a chip unit illustrated in FIG. 4.

FIG. 6 illustrates an example unfolded state of the chip unit illustrated in FIG. 5.

FIG. 7 schematically illustrates a semiconductor device according to a third embodiment.

FIG. 8 is a schematic plan view illustrating a semiconductor device according to a fourth embodiment.

FIG. 9A illustrates a step of manufacturing a chip unit illustrated in FIG. 8.

FIG. 9B illustrates the step subsequent to that in FIG. 9A.

FIG. 9C illustrates the step subsequent to that in FIG. 9B.

FIG. 10 is a side view illustrating an example configuration of a chip unit including four semiconductor chips.

FIG. 11A illustrates a step of manufacturing the chip unit illustrated in FIG. 10.

FIG. 11B illustrates the step subsequent to that in FIG. 11A.

FIG. 12 illustrates an example configuration of another chip unit including four or more semiconductor chips.

FIG. 13 is a perspective view illustrating another example of a semiconductor device.

### DETAILED DESCRIPTION

Embodiments of the present invention will now be described with reference to the drawings. The same components will be labeled with the same reference numerals throughout the drawings to omit redundant description thereof. The dimensions in the drawings do not always correspond with those in the description. Terms indicating positional relationships, such as “over” and “under,” are used for the convenience of description based on the drawings.

### First Embodiment

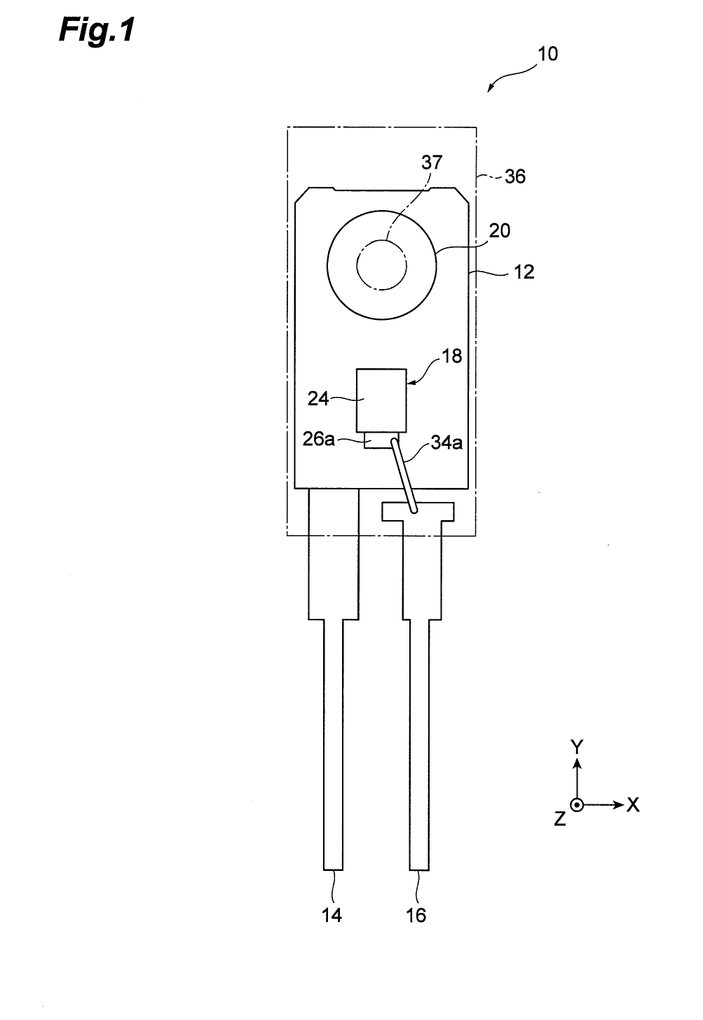

FIG. 1 is a schematic plan view illustrating a semiconductor device according to a first embodiment. The semiconductor device 10 in FIG. 1 is a resin-sealed type semiconductor device.

The semiconductor device 10 includes a die pad 12, leads 14 and 16, and a chip unit 18.

The die pad 12 is a substrate which has conductivity and on which the chip unit 18 is mounted. An example planar configuration of the die pad 12 (the shape viewed from the plate thickness direction) is a rectangle. Examples of the material of the die pad 12 include metals such as copper (Cu) and copper alloy. The die pad 12 may have a through hole 20 therethrough in the plate thickness direction. The through hole 20 receives a screw, for example, for the fixation of the semiconductor device 10 to any other member.

Hereinafter, the plate thickness direction of the die pad 12 is referred to as the Z direction, and two directions at right angles to the Z direction as the X and Y directions. The X direction is orthogonal to the Y direction. If the planar configuration of the die pad 12 is a rectangle, the X direction corresponds to the short-side direction while the Y direction corresponds to the long-side direction.

The leads 14 and 16 are arranged along the X direction. The leads 14 and 16 and the die pad 12 can configure a lead frame. The inner end of the lead 14 is mechanically (or physically) integrated into the die pad 12. Examples of the material of the lead 14 include that of the die pad 12. Examples of the material of the lead 16 include metals such as copper and copper alloy.

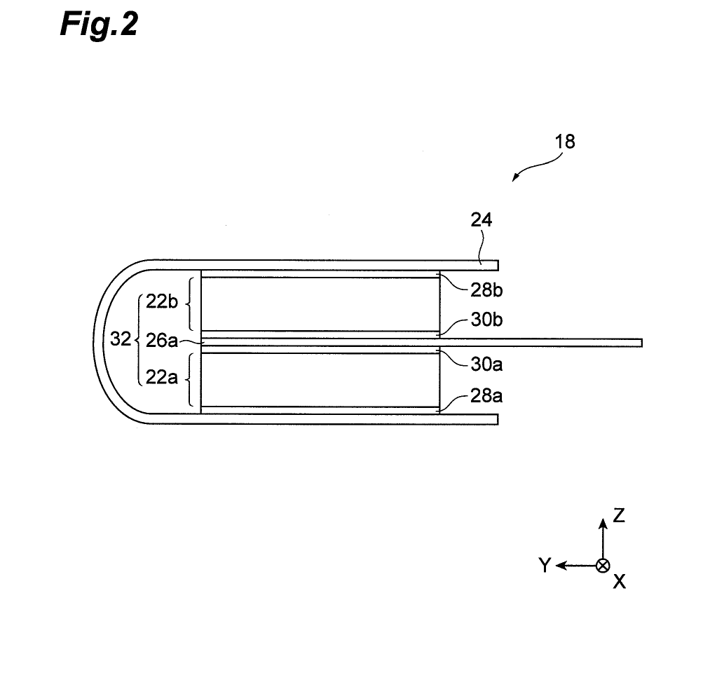

The chip unit 18 is mounted at a predetermined position on the die pad 12. The configuration of the chip unit 18 will now be described with reference to FIG. 2. FIG. 2 is a side view of the chip unit.

The chip unit 18 includes a semiconductor chip (first semiconductor chip) 22a, a semiconductor chip (second semiconductor chip) 22b, a chip-mount substrate 24 on which the semiconductor chips 22a and 22b are mounted, and a wiring terminal (first wiring terminal) 26a.

The semiconductor chips 22a and 22b of the first embodiment are diodes. An example of the diode is a Schottky barrier diode. The semiconductor chip 22a has a cathode electrode 28a and an anode electrode 30a as a first electrode and a second electrode thereof, respectively, which are disposed at opposite sides of the semiconductor chip 22a in the thickness direction (the predetermined direction, i.e., the Z direction in FIG. 2). Similarly, the semiconductor chip 22b has a cathode electrode 28b and an anode electrode 30b as a first electrode and a second electrode thereof, respectively, which are disposed at opposite sides of the semiconductor chip 22b in the thickness direction (the predetermined direction, i.e., the Z direction in FIG. 2).

Examples of the material of the semiconductor chips 22a and 22b include a wide band gap semiconductor, silicon, and other semiconductors. The wide band gap semiconductor has a band gap wider than that of silicon. Examples of the wide band gap semiconductor include silicon carbide (SiC), gallium nitride (GaN), and diamond.

The semiconductor chip 22b lies over the semiconductor chip 22a in the Z direction. The anode electrode 30b of the semiconductor chip 22b and the anode electrode 30a of the semiconductor chip 22a face each other across the wiring terminal 26a. In this configuration, both ends, in the Z direction, of a laminate 32 composed of the semiconductor chip 22a, the wiring terminal 26a, and the semiconductor chip 22b correspond to the cathode electrodes 28a and 28b.

The wiring terminal 26a is a plate having conductivity. An example of the plate is a metal plate. The metal plate is made of copper, for example. The anode electrodes 30a and 30b of the semiconductor chips 22a and 22b, respectively, are bonded to the wiring terminal 26a so as to provide electrical connection therebetween. The anode electrodes 30a and 30b may be bonded to the wiring terminal 26a by soldering, for example.

The chip-mount substrate 24 is a plate having conductivity. The chip-mount substrate 24 is U-shaped so as to enclose the laminate 32, as illustrated in FIG. 2. In one embodiment, the chip-mount substrate 24 may be made of a conductive material having flexibility that is capable of being bent. The chip-mount substrate 24 may have a thickness that is capable of being bent. The chip-mount substrate 24 is a metal plate, for example. The metal plate is made of copper, for example.

The semiconductor chips 22a and 22b, which are disposed inside the U-shaped chip-mount substrate 24, are mounted by bonding the cathode electrodes 28a and 28b to the chip-mount substrate 24, e.g. by using a conductive material such as solder. The cathode electrodes 28a and 28b are thereby electrically connected to the chip-mount substrate 24. The cathode electrodes 28a and 28b of this configuration are connected with each other via the chip-mount substrate 24. In the configuration of the chip unit 18, a mount area for the semiconductor chip 22a and a mount area for the semiconductor chip 22b on a surface of the chip-mount substrate 24 (the U-shaped inner face) face each other.

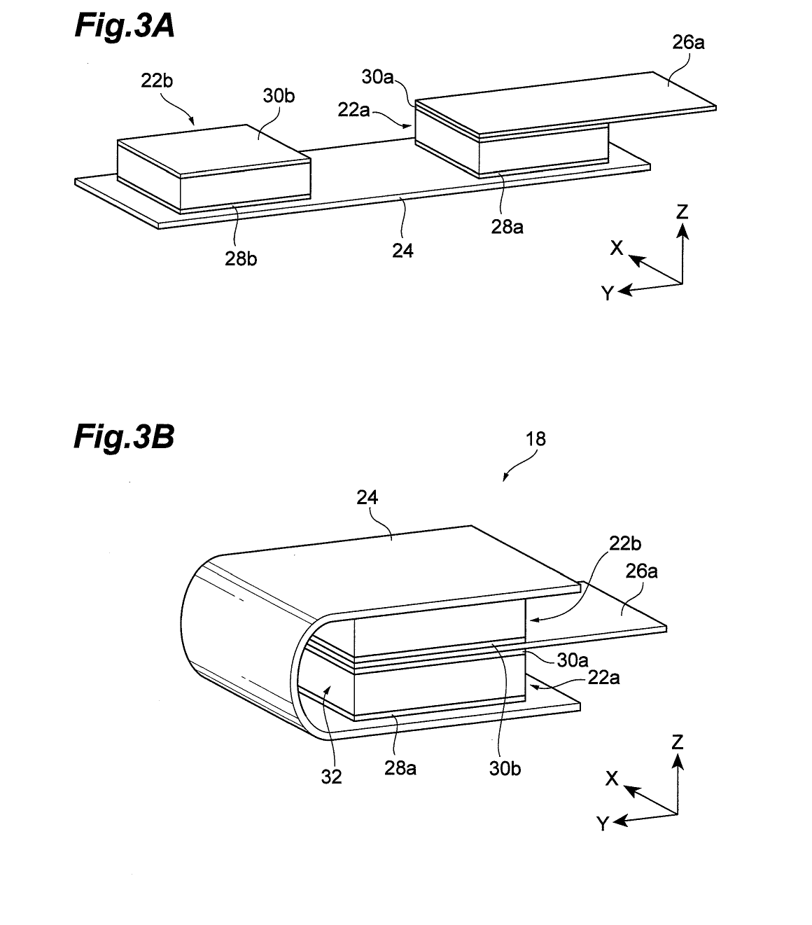

FIG. 3A illustrates a step of manufacturing the chip unit 18 illustrated in FIG. 2. FIG. 3B illustrates the step subsequent to that in FIG. 3A.

The semiconductor chips 22a and 22b are mounted at some distance from each other on the planar chip-mount substrate 24, as illustrated in FIG. 3A. The wiring terminal 26a is then bonded onto the anode electrode 30a of the semiconductor chip 22a.

Thereafter, the chip-mount substrate 24 is bent such that the semiconductor chip 22b lies over the semiconductor chip 22a. As an example, the chip-mount substrate 24 is bent such that the mount areas for the semiconductor chips 22a and 22b on the surface of the chip-mount substrate 24 face each other. The anode electrode 30b of the semiconductor chip 22b and the wiring terminal 26a are bonded to each other when the semiconductor chip 22b is disposed over the semiconductor chip 22a. As a result, the chip unit 18 is completed.

Referring back to FIG. 1, the configuration of the semiconductor device will be further described.

The chip unit 18 is mounted on the die pad 12 with a conductive material such as solder so that the chip-mount substrate 24 is electrically connected to the die pad 12. The chip-mount substrate 24 is electrically connected to the cathode electrodes 28a and 28b, and the die pad 12 and the lead 14 are also electrically connected to each other. Thus, the cathode electrodes 28a and 28b are electrically connected to the lead 14. In this configuration, the lead 14 functions as a cathode terminal. The wiring terminal 26a of the chip unit 18 is connected to the lead 16 via a wiring 34a. Examples of the material of the wiring 34a include metals such as aluminum, gold, and copper. The wiring 34a is connected to the lead 16 and the wiring terminal 26a by wire bonding that utilizes ultrasound or pressurization, for example. Since the wiring terminal 26a is electrically connected to the anode electrodes 30a and 30b, the lead 16 functions as an anode terminal. Thus, external connection of the leads 14 and 16 allows the use of the two semiconductor chips 22a and 22b, which are diodes.

The die pad 12 and the chip unit 18 can be sealed with a resin member 36. For the convenience of description, the resin member 36 is indicated by dash-dot lines in FIG. 1 (and other drawings). The inner end of the lead 16 is fixed to the resin member 36. The parts of the leads 14 and 16 inside the resin member 36 are inner leads; whereas the parts outside the resin member 36 are outer leads. The profile of the resin member 36 is a substantially rectangular parallelepiped, for example. Examples of the material of the resin member 36 include thermoplastic resins such as polyphenylene sulfide (PPS) resins and liquid crystal polymers.

The resin member 36 can be formed by molding the die pad 12 and the chip unit 18 with thermoplastic resin. The resin member 36 has a through hole 37, the central axis of which corresponds to that of the through hole 20 in the die pad 12. The through hole 37 is used to insert a screw, similar to the through hole 20. The diameter of the through hole 37 is smaller than that of the through hole 20.

Since the two semiconductor chips 22a and 22b of the semiconductor device 10 are stacked in the thickness direction (predetermined direction), the two semiconductor chips 22a and 22b can be contained on the die pad 12 within an area for one semiconductor chip. That is, the area for mounting the two semiconductor chips 22a and 22b on the die pad 12 can be reduced compared with a two-dimensional arrangement of the two semiconductor chips 22a and 22b.

A wide band gap semiconductor has low production yields of a semiconductor chip and is expensive compared with silicon. As a result, one large semiconductor chip produced with a wide band gap semiconductor similar to silicon would cause lowered production yields and increased manufacturing costs. For this reason, when using a wide band gap semiconductor, it may be necessary to mount a plurality of small semiconductor chips on the die pad 12, instead of one large semiconductor chip.

The configuration of the semiconductor device 10 allows the semiconductor chips 22a and 22b to be efficiently disposed on the single die pad 12. Thus, the configuration of the semiconductor device 10 can be more effective for the semiconductor chips 22a and 22b produced with a wide band gap semiconductor. Furthermore, a semiconductor chip produced with a wide band gap semiconductor has higher breakdown voltage characteristic than that of a semiconductor chip made of silicon. Thus, a semiconductor chip produced with a wide band gap semiconductor may be thinner than that made of silicon. For this reason, the stack of the semiconductor chips 22a and 22b may be more effective in the case of these chips being produced with a wide band gap semiconductor.

In the first embodiment, first electrodes bonded to the chip-mount substrate are the cathode electrodes 28a and 28b, whereas second electrodes bonded to the wiring terminal (first wiring terminal) 26a are the anode electrodes 30a and 30b; however, the first electrodes bonded to the chip-mount substrate may be anode electrodes, whereas the second electrodes bonded to the wiring terminal (first wiring terminal) 26a may be cathode electrodes.

### Second Embodiment

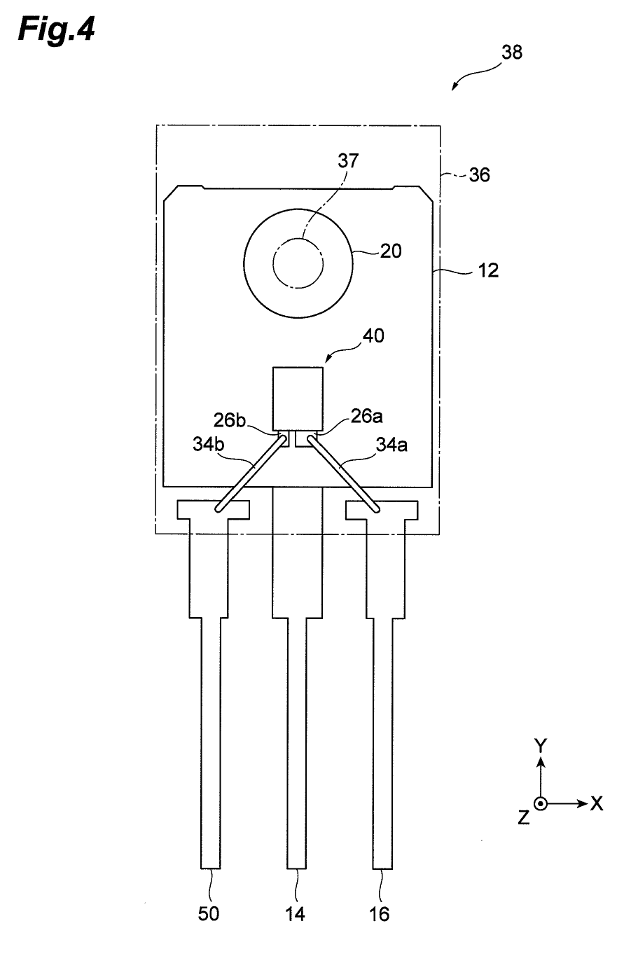

FIG. 4 is a schematic plan view illustrating the configuration of a semiconductor device according to a second embodiment. The semiconductor device 38 is different from the semiconductor device 10 chiefly in that the chip unit 18 is replaced with a chip unit 40. The semiconductor device 38 will now be described by focusing on this difference.

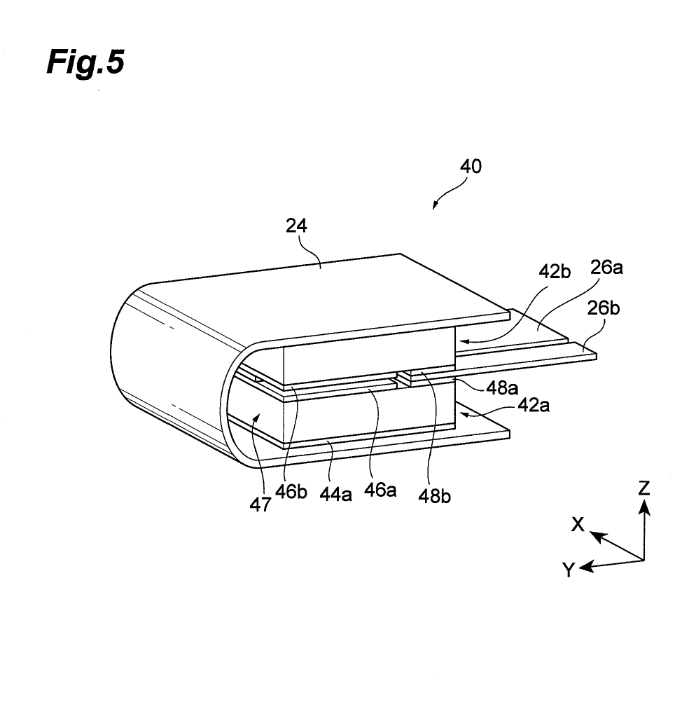

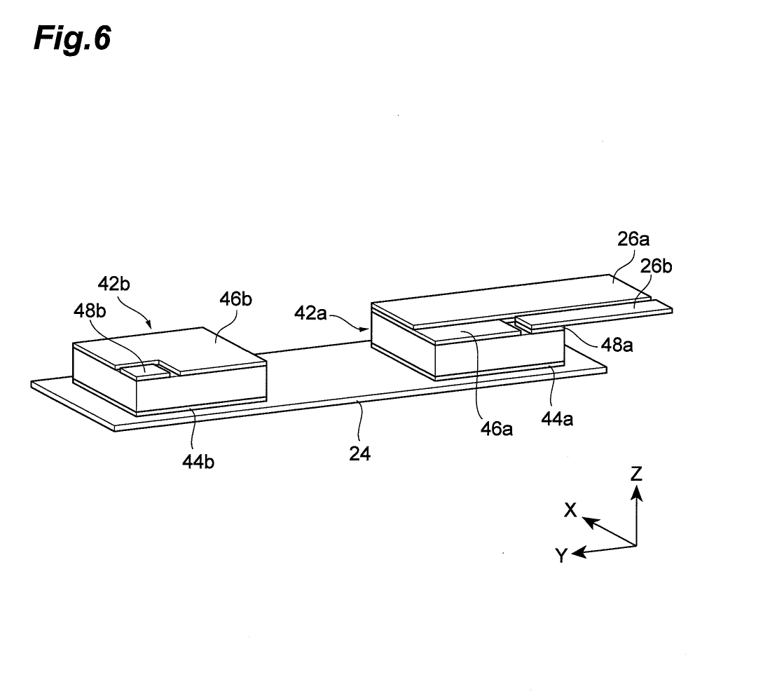

The chip unit 40 will be described with reference to FIGS. 5 and 6. FIG. 5 is a perspective view of the chip unit illustrated in FIG. 4. FIG. 6 illustrates an example unfolded state of the chip unit.

The chip unit 40 includes a semiconductor chip (first semiconductor chip) 42a, a semiconductor chip (second semiconductor chip) 42b, the chip-mount substrate 24, a wiring terminal (first wiring terminal) 26a, and a wiring terminal (second wiring terminal) 26b.

The semiconductor chips 42a and 42b in the second embodiment are transistors. Examples of the transistors include metal-oxide-semiconductor field-effect transistors (MOS-FETs) and insulated gate bipolar transistors (IGBTs). In the following description, the semiconductor chips 42a and 42b are MOS-FETs, unless otherwise specified. The material of the semiconductor chips 42a and 42b may be the same as that of the semiconductor chips 22a and 22b.

The semiconductor chips 42a and 42b respectively include drain electrodes 44a and 44b as first electrodes, the source electrode pads 46a and 46b as second electrodes, which are positioned opposite to the first electrodes in the Z direction, and gate electrode pads 48a and 48b as third electrodes. The gate electrode pads 48a and 48b of the semiconductor chips 42a and 42b are disposed at the same side of the source electrode pads 46a and 46b, respectively, as illustrated in FIG. 6.

The semiconductor chip 42b lies over the semiconductor chip 42a in the Z direction. The source electrode pad 46b of the semiconductor chip 42b and the source electrode pad 46a of the semiconductor chip 42a face each other across the wiring terminal 26a. The gate electrode pad 48b of the semiconductor chip 42b and the gate electrode pad 48a of the semiconductor chip 42b face each other across the wiring terminal 26b. In this configuration, both ends, in the Z direction, of a laminate 47 composed of the semiconductor chips 42a and 42b and the wiring terminals 26a and 26b correspond to the drain electrodes 44a and 44b.

The wiring terminals 26a and 26b are plates having conductivity. Examples of the material of the wiring terminals 26a and 26b are the same as those of the wiring terminal 26a described in the first embodiment; hence, description thereof will be omitted. The source electrode pads 46a and 46b are bonded to the wiring terminal 26a so as to provide electrical connection therebetween. The source electrode pads 46a and 46b may be bonded to the wiring terminal 26a by soldering, for example. As a result, the source electrode pads 46a and 46b and the wiring terminal 26a are electrically connected to each other. Similarly, the gate electrode pads 48a and 48b are bonded to the wiring terminal 26b so as to provide electrical connection therebetween. An example of a method of bonding may be the same as that of the source electrode pads 48a and 48b. As a result, the gate electrode pads 48a and 48b and the wiring terminal 26b are electrically connected to each other.

The configuration of the chip-mount substrate 24 is the same as that in the first embodiment; hence, description thereof will be omitted. The semiconductor chips 42a and 42b, which are disposed inside the U-shaped chip-mount substrate 24, are mounted by bonding the drain electrodes 44a and 44b to the chip-mount substrate 24, e.g. by using a conductive material such as solder. The drain electrodes 44a and 44b are thereby electrically connected to the chip-mount substrate 24. The drain electrodes 44a and 44b of this configuration are connected with each other via the chip-mount substrate 24. In the configuration of the chip unit 40, a mount area for the semiconductor chip 42a and a mount area for the semiconductor chip 42b on a surface of the chip-mount substrate 24 face each other.

Example steps of manufacturing the chip unit 40 will now be described. First, the semiconductor chips 42a and 42b are mounted at some distance from each other on the planar chip-mount substrate 24, as illustrated in FIG. 6. The wiring terminals 26a and 26b are then bonded onto the source electrode pad 46a and the gate electrode pad 48a of the semiconductor chip 42a, respectively, for example.

Thereafter, the chip-mount substrate 24 is bent such that the semiconductor chip 42b lies over the semiconductor chip 42a. The source electrode pad 46b and the gate electrode pad 48b are bonded to the wiring terminal 26a and the wiring terminal 26b, respectively, when the semiconductor chip 42b is disposed over the semiconductor chip 42a. As a result, the chip unit 40 is completed.

Referring back to FIG. 4, the configuration of the semiconductor device 38 will be described. The chip unit 40 is mounted on the die pad 12 in the same manner as the chip unit 18. Thus, the chip-mount substrate 24 and the die pad 12 are electrically connected to each other also in the second embodiment. The chip-mount substrate 24 is electrically connected to the drain electrodes 44a and 44b, and the die pad 12 and the lead 14 are also electrically connected to each other. Thus, the drain electrodes 44a and 44b are electrically connected to the lead 14. In this configuration, the lead 14 functions as a drain electrode terminal.

The wiring terminal 26a of the chip unit 40 is connected to the lead 16 via the wiring 34a. Since the wiring terminal 26a is electrically connected to the source electrode pads 46a and 46b, the source electrode pads 46a and 46b are electrically connected to the lead 16. In this configuration, the lead 16 functions as a source electrode terminal.

The semiconductor device 38 further includes a lead 50 connected to the wiring terminal 26b of the chip unit 40 via a wiring 34b. The lead 50 may be aligned along the leads 14 and 16. The leads 14, 16, and 50 and the die pad 12 can configure a lead frame. Since the wiring terminal 26b is electrically connected to the gate electrode pads 48a and 48b, the gate electrode pads 48a and 48b are also electrically connected to the lead 50. In this configuration, the lead 50 functions as a gate electrode terminal. Examples of wirings 34a and 34b may be similar to that of wiring 34a described in the first embodiment.

In this configuration, external connection of the leads 14, 16, and 50 allows the supply of predetermined power to the drain electrodes 44a and 44b and the source electrode pads 46a and 46b, and also allows the supply of predetermined signals to the gate electrode pads 48a and 48b. As a result, the semiconductor chips 42a and 42b, which are MOS-FETs, can be driven.

The die pad 12 and the chip unit 40 can be sealed with the resin member 36 similar to the first embodiment. This embodiment is analogous to the first embodiment in the method of forming the resin member 36 and the through hole 37 provided therein.

The two semiconductor chips 42a and 42b of the chip unit 40 are stacked in the Z direction, also in the semiconductor device 38 according to the second embodiment. Thus, the semiconductor device 38 provides at least the same functional effect as that by the semiconductor device 10.

### Third Embodiment

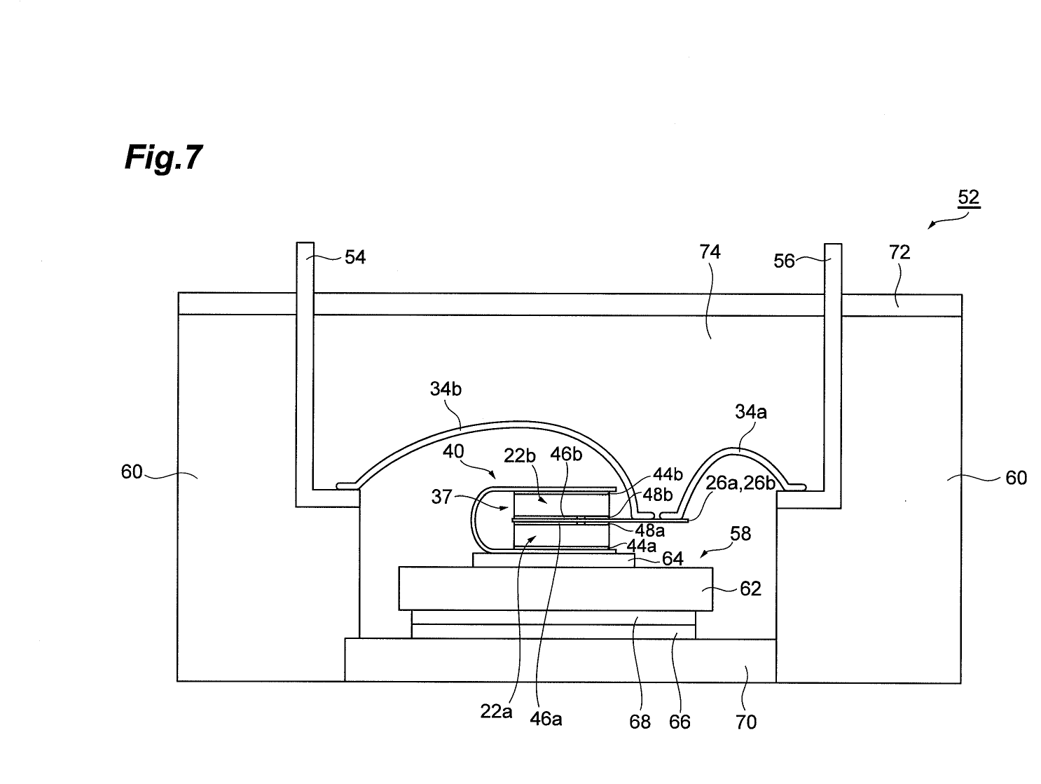

FIG. 7 schematically illustrates a semiconductor device according to a third embodiment. The semiconductor device 52 illustrated in FIG. 7 is a case type semiconductor device. The semiconductor device 52 includes the chip unit 40, a gate electrode terminal 54, a source electrode terminal 56, a wiring substrate 58, and a case 60. The chip unit 40 has the same configuration as that in the second embodiment; hence, description thereof will be omitted. A drain electrode terminal is not illustrated in FIG. 7.

The wiring substrate 58 includes an insulating substrate 62 and a wiring layer 64 which are formed on a surface of the insulating substrate 62. The chip unit 40 is mounted on the wiring layer 64 of the wiring substrate 58 such that the chip-mount substrate 24 of the chip unit 40 is electrically connected thereto. For example, the chip unit 40 is bonded to the wiring layer 64 with conductive materials such as solder.

A heat-dissipating layer 66 may be provided on the back of the wiring substrate 58 (the surface opposite to the chip unit 40). Examples of the material of the heat-dissipating layer 66 include metals such as copper and copper alloy. The heat-dissipating layer 66 is bonded to a heat sink 70 with a bonding layer 68 composed of solder, for example. Examples of the material of the heat sink 70 include metals.

The chip unit 40, the wiring substrate 58, and the heat-dissipating layer 66 are housed in the case 60. The case 60 is tubular, for example. One opening of the case 60 may be sealed with the heat sink 70, whereas the other opening may be sealed with a lid 72. Examples of the material of the case 60 include engineering plastics such as polybutylene terephthalate (PBT) and polyphenylene sulfide (PPS) resins. Examples of the material of the lid 72 include thermoplastic resins. Gel 74 such as silicone gel may be poured into the case 60 for the purpose of stress relief.

The wiring terminal 26a of the chip unit 40 is connected to the source electrode terminal 56 via the wiring 34a. The wiring terminal 26b of the chip unit 40 is connected to the gate electrode terminal 54 via the wiring 34b. Although the wiring terminals 26a and 26b in FIG. 7, which is a side view of the chip unit 40, overlap one another, the wiring terminals 26a and 26b are separated from each other, as illustrated in FIGS. 5 and 6.

The gate electrode terminal 54 and the source electrode terminal 56 of the semiconductor device 52 are provided on the inner surface of the case 60. The gate electrode terminal 54 and the source electrode terminal 56 extend along the inner surface of the case 60 and protrude from openings provided in the lid 72.

The semiconductor device 52 according to the third embodiment provides at least the same functional effect as that by the semiconductor device 10.

### Fourth Embodiment

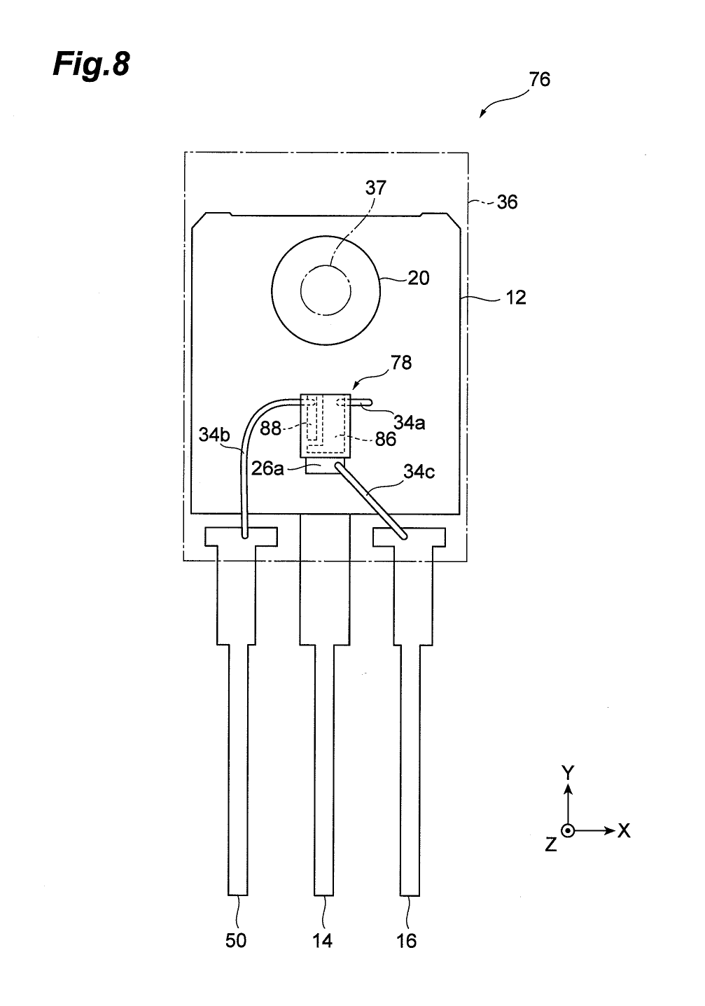

FIG. 8 is a schematic plan view of the configuration of a semiconductor device according to a fourth embodiment. The semiconductor device 76 is a resin-sealed type semiconductor device similar to the second embodiment. The semiconductor device 76 is different from the semiconductor device 76 chiefly in that the chip unit 40 is replaced with a chip unit 78. The semiconductor device 76 will now be described by focusing on this difference.

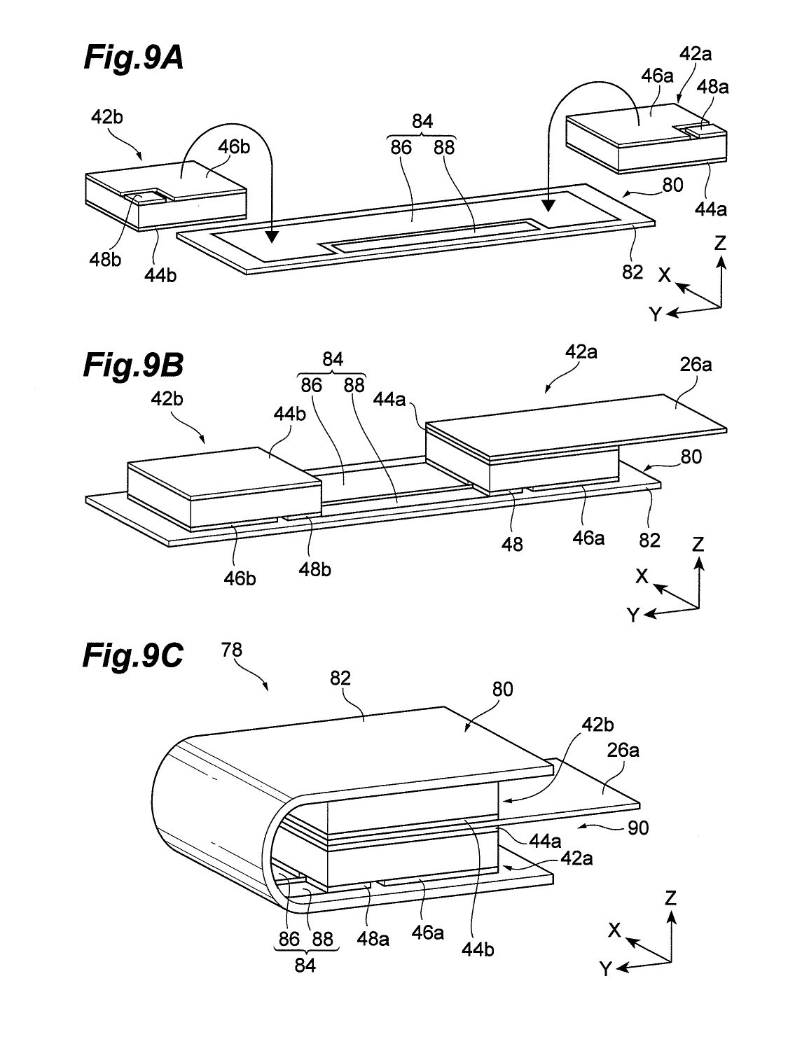

The chip unit 78 (see FIG. 9C) includes the semiconductor chip 42a, the semiconductor chip 42b, a chip-mount substrate 80, and the wiring terminal 26a. The semiconductor chips 42a and 42b have the same configurations as those in the second embodiment. The material of the wiring terminal 26a may be the same as that of the wiring terminal 26a described in the first and second embodiments.

For simplicity, the chip unit 78 will be described in association with steps of manufacturing the chip unit 78. FIG. 9A illustrates a step of manufacturing the chip unit illustrated in FIG. 8. FIG. 9B illustrates the step subsequent to that in FIG. 9A. FIG. 9C illustrates the step subsequent to that in FIG. 9B.

The planar chip-mount substrate 80 is prepared, as illustrated in FIG. 9A. The chip-mount substrate 80 is a flexible printed wiring substrate (FPC: flexible printed circuit) in which a wiring layer 84 is printed on a flexible insulating substrate 82. The wiring layer 84 includes at least wiring regions 86 and 88. The wiring region 86 is electrically connected to the source electrode pads 46a and 46b, whereas the wiring region 88 is electrically connected to the gate electrode pads 48a and 48b. The semiconductor chips 42a and 42b are mounted on the chip-mount substrate 80 such that the source electrode pads 46a and 46b are bonded onto the wiring region 86, and the gate electrode pads 48a and 48b are bonded onto the wiring region 88.

The wiring terminal 26a is then bonded to the drain electrode 44a of the semiconductor chip 42a, as illustrated in FIG. 9B, such that they are electrically connected to each other.

Thereafter, the chip-mount substrate 80 is bent such that the drain electrode 44a of the semiconductor chip 42a and the drain electrode 44b of the semiconductor chip 42b face each other across the wiring terminal 26a, as illustrated in FIG. 9C. At this time, the drain electrode 44b is bonded to the wiring terminal 26a so as to provide electrical connection therebetween. As a result, the chip unit 78 is completed.

The semiconductor chip 42b lies over the semiconductor chip 42a in the chip unit 78. The drain electrodes 44a and 44b of the semiconductor chips 42a and 42b, respectively, face each other across the wiring terminal 26a. In this configuration, both ends, in the Z direction, of a laminate 90 composed of the semiconductor chips 42a and 42b and the wiring terminal 26a correspond to the source and gate electrode pads 46a and 48a of the semiconductor chip 42a, and the source and gate electrode pads 46b and 48b of the semiconductor chip 42b.

The chip-mount substrate 80 of the chip unit 78 is U-shaped. The semiconductor chip 42a, which is disposed inside the U-shaped chip-mount substrate 24, is mounted by bonding the source electrode pad 46a and the gate electrode pad 48a to the wiring region 86 and the wiring region 88. Similarly, the semiconductor chip 42b, which is disposed inside the U-shaped chip-mount substrate 24, is mounted by bonding the source electrode pad 46b and the gate electrode pad 48b to the wiring region 86 and the wiring region 88. The drain electrodes 44a and 44b are bonded to the wiring terminal 26a. The source electrode pads 46a and 46b are electrically connected to the wiring region 86, and the gate electrode pads 48a and 48b are electrically connected to the wiring region 88. The drain electrodes 44a and 44b are also electrically connected to the wiring terminal 26a.

In this configuration, first electrodes included in the semiconductor chips 42a and 42b and bonded to the chip-mount substrate 80 correspond to the source electrode pads 46a and 46b, whereas second electrodes opposite to the first electrodes in the Z direction and bonded to the wiring terminal 26a correspond to the drain electrodes 44a and 44b. The gate electrode pads 48a and 48b, which correspond to third electrodes in the semiconductor chips 42a and 42b, respectively, are disposed at the same side of the source electrode pads 46a and 46b, that is, at the side of the first electrodes in the fourth embodiment.

In the configuration of the chip unit 78 illustrated in FIG. 9C, the source electrode pads 46a and 46b are connected with each other via the chip-mount substrate 80. The gate electrode pads 48a and 48b are connected with each other via the chip-mount substrate 80. This embodiment is analogous to the second embodiment in that the mount area for the semiconductor chip 42a faces the mount area for the semiconductor chip 42b on the same surface of the chip-mount substrate 80 of the chip unit 78.

Referring back to FIG. 8, the configuration of the semiconductor device 76 will now be further described. The chip unit 78 is mounted on the die pad 12. Since the exterior of the chip unit 78 is the insulating substrate 82, the chip unit 78 may be bonded to the die pad 12 by any method.

The wiring region 86 of the chip-mount substrate 80 is electrically connected to the die pad 12 via the wiring 34a. Since the die pad 12 is electrically connected to the lead 14, the wiring region 86 and the lead 14 are also electrically connected to each other. As a result, the source electrode pads 46a and 46b are electrically connected to the lead 14. In this configuration, the lead 14 functions as a source electrode terminal.

The wiring region 88 of the chip-mount substrate 80 is electrically connected to the lead 50 via the wiring 34b. The gate electrode pads 48a and 48b are thereby electrically connected to the lead 50. In this configuration, the lead 50 functions as a gate electrode terminal.

Furthermore, the wiring terminal 26a and the lead 16 are electrically connected to each other via a wiring 34c. The wiring 34c may be similar to the wirings 34a and 34b. In this case, the drain electrodes 44a and 44b are electrically connected to the lead 16. In this configuration, the lead 16 functions as a drain electrode terminal.

The die pad 12 and the chip unit 78 can be sealed with the resin member 36 similar to the first embodiment. This embodiment is analogous to the first embodiment in the method of forming the resin member 36 and the through hole 37 provided in the resin member.

The two semiconductor chips 42a and 42b of the chip unit 78 are stacked in the Z direction, also in the semiconductor device 76 according to the fourth embodiment. Thus, the semiconductor device 76 provides at least the same functional effect as that by the semiconductor device 10. Although the chip-mount substrate 80 in the fourth embodiment is a flexible printed wiring substrate, the chip-mount substrate 80 may be any bendable wiring substrate that includes the wiring layer 84 having the wiring regions 86 and 88.

Although the exemplary embodiments of the present invention have been described in detail, the present invention is not limited to the embodiments above.

For example, the first to fourth embodiments each illustrate the semiconductor device including the two semiconductor chips; however, the semiconductor device may also include four or more semiconductor chips. Such a semiconductor device including four or more semiconductor chips is different from the above-described semiconductor devices chiefly in the configuration of a chip unit; hence, the chip unit configuration will be mainly described.

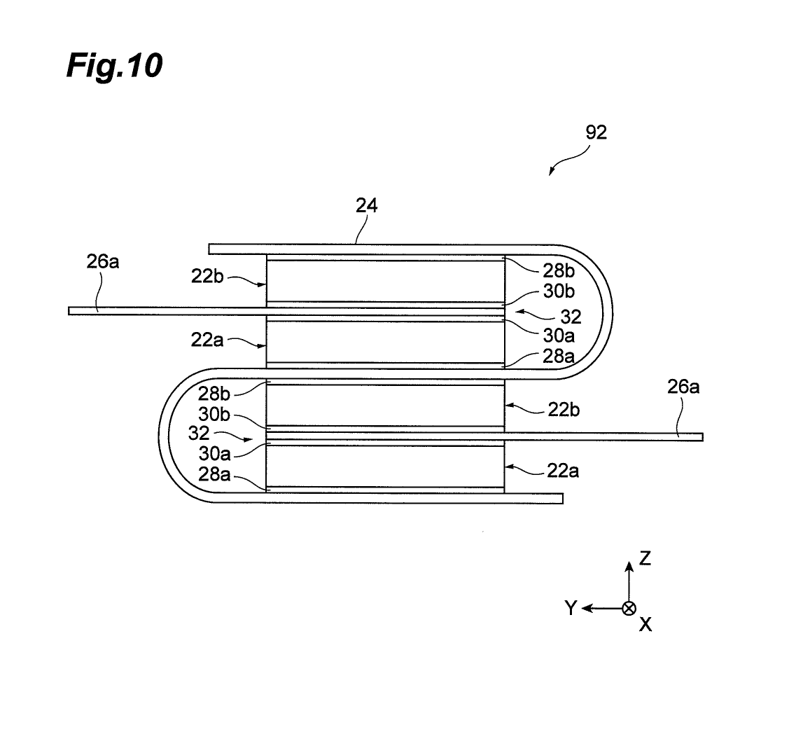

FIG. 10 is a side view illustrating an example configuration of a chip unit including four semiconductor chips. The chip unit 92 illustrated in FIG. 10 includes two laminates 32 each equivalent to the laminate 32 described in the first embodiment. Each of the laminates 32 is composed by stacking the semiconductor chip 22a, the wiring terminal 26a, and the semiconductor chip 22b, as described in the first embodiment. The two laminates 32 are stacked in the Z direction. The chip-mount substrate 24 of the chip unit 92 is bent such that the cathode electrodes 28a of the semiconductor chips 22a and 22b in the laminates 32 are connected with each other.

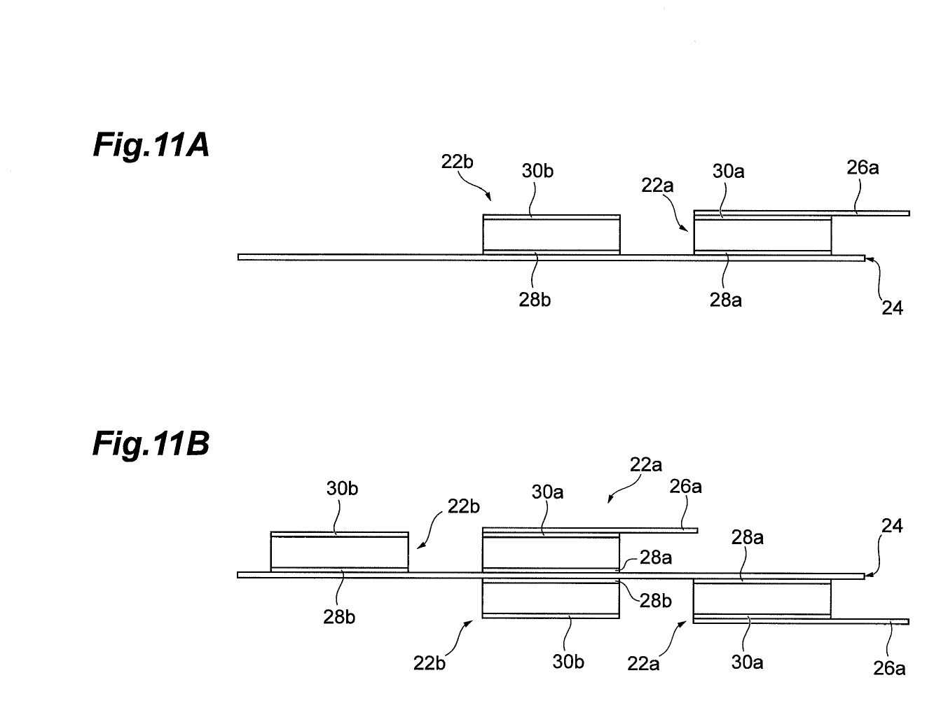

The chip unit 92 can be made by, for example, bending the chip-mount substrate 24 on which the semiconductor chips 22a and 22b are mounted, as illustrated in FIGS. 11A and 11B. FIG. 11A illustrates a step of manufacturing the chip unit in FIG. 10. FIG. 11B illustrates the step subsequent to that in FIG. 11A.

Specifically, semiconductor chips 22a and 22b are mounted on a surface of one end of the chip-mount substrate 24, as illustrated in FIG. 11A. The mounting method is the same as that in the first embodiment. A wiring terminal 26a is then bonded to the anode electrode 30a of the semiconductor chip 22a so as to provide electrical connection therebetween.

The other two semiconductor chips 22a and 22b are then mounted on the rear surface of the chip-mount substrate 24. When doing so, the other semiconductor chip 22a is mounted on the rear surface such that the other semiconductor chip 22a is positioned opposite the semiconductor chip 22b mounted on the surface of the chip-mount substrate 24. The other semiconductor chip 22b is mounted on the chip-mount substrate 24 on the end opposite to the end on which the semiconductor chip 22a mounted under the step of FIG. 11A is disposed. The mounting method is the same as that in the embodiment. A wiring terminal 26a is then bonded to the anode electrode 30a of the semiconductor chip 22a so as to provide electrical connection therebetween. Thereafter, the chip-mount substrate 24 is bent such that, of the two semiconductor chips 22a and 22b positioned on the same surface side of the chip-mount substrate 24, the semiconductor chip 22b is positioned over the semiconductor chip 22a, and the wiring terminal 26a and the anode electrode 30b of the semiconductor chip 22b are bonded so as to provide electrical connection therebetween. As a result, the chip unit 92 as illustrated in FIG. 10 is completed.

A semiconductor device including four semiconductor chips may be made by mounting the chip unit 92 on a die pad and providing predetermined wiring.

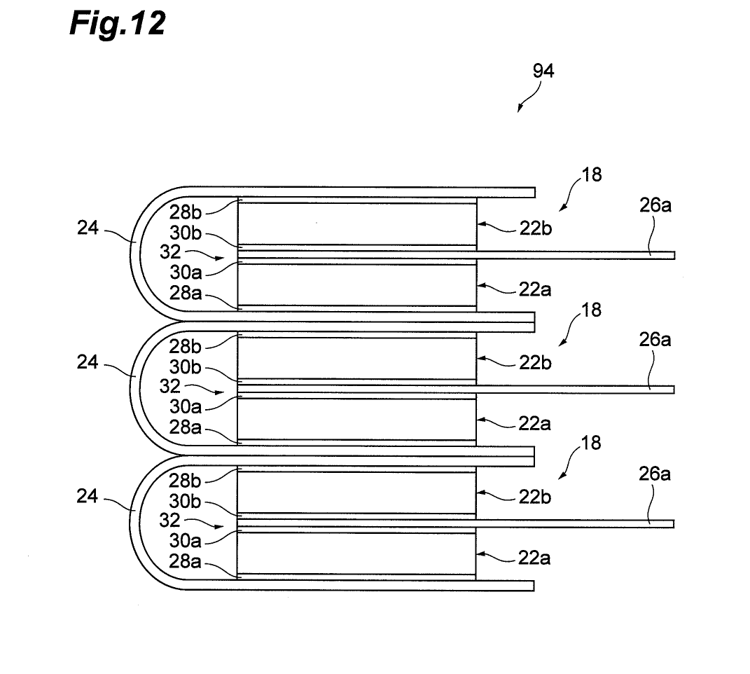

FIG. 12 illustrates an example configuration of another chip unit including four or more semiconductor chips. The chip unit 94 illustrated in FIG. 12 may include a laminate of the chip units 18 each described in the first embodiment. A semiconductor device including six semiconductor chips, for example, can be completed by mounting the chip unit 94 on a die pad and providing predetermined wiring.

The chip unit illustrated in FIG. 12 composed of the laminate of the multiple chip units 18 has as many chip-mount substrates 24, which enclose the laminates 32, as the laminated chip units 18; however, the chip unit 94 may also include a single chip-mount substrate 24. In this case, the single chip-mount substrate 24 is bent such that the cathode electrodes 28a and 28b of the stacked laminates 32 are connected with each other.

These modifications have been described using the semiconductor chips 22a and the semiconductor chips 22b described in the first embodiment, which are diodes; however, the modifications may also use the semiconductor chips 42a and the semiconductor chips 42b, which are transistors. In this case, the laminates 32 and the chip units 18 in the chip units 92 and 94 illustrated in FIGS. 10 and 12, respectively, may be replaced with the laminates 47 (or the laminates 90) and the chip units 40 (or the chip units 78), respectively.

In the second to fourth embodiments, the semiconductor chips 42a and 42b, which are transistors, are MOS-FETs. The semiconductor chips 42a and 42b may not limited to the MOS-FETs, may also be insulated gate bipolar transistors (IGBT), as described above. In the semiconductor chips 42a and 42b including IGBTs, electrodes as the source electrode pads 46a and 46b described in the second to fourth embodiments correspond to emitter electrode pads, and electrodes as the drain electrodes 44a and 44b correspond to collector electrodes.

Although the first and fourth embodiments each illustrate the resin-sealed type semiconductor device as an example, the semiconductor devices in the first and fourth embodiments and such devices including the chip units in FIGS. 11 and 12 in the first and fourth embodiments may also be case type semiconductor devices, as described in the third embodiment. In this case, the chip unit in the third embodiment may be replaced with that in the first or fourth embodiment and predetermined wiring may be provided.

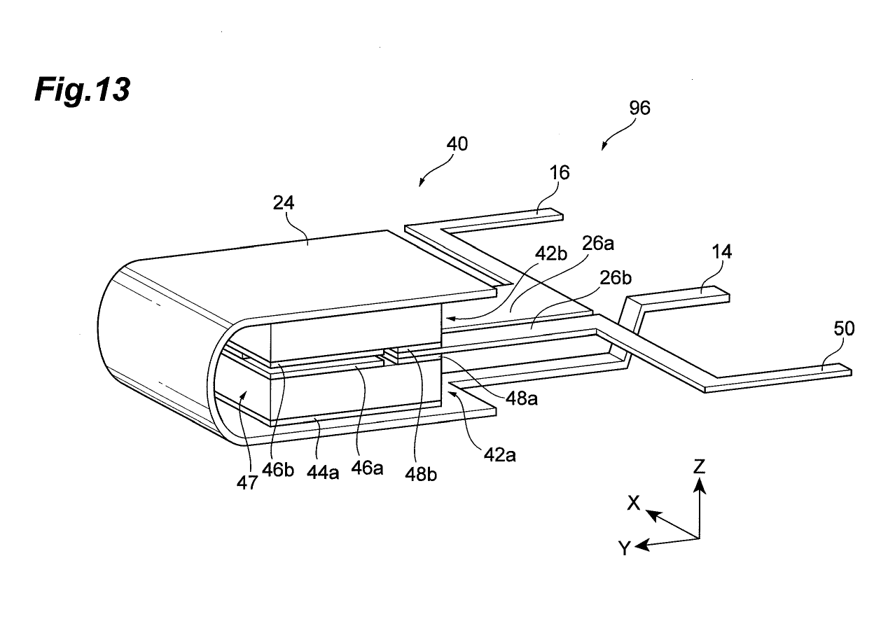

The first to fourth embodiments each illustrate the resin-sealed type or case type semiconductor device in which the chip unit is independently mounted on the die pad or wiring substrate. Although the chip unit of such a semiconductor device is electrically connected to the lead for external connection or the electrode terminal via wire, terminals for external connection may also be connected to the chip unit itself. The configuration will now be specifically described with reference to FIG. 13.

FIG. 13 is a perspective view illustrating another example of a semiconductor device. The semiconductor device 96 in FIG. 13 includes the chip unit 40, described in the second embodiment, with which the leads 14, 16, and 50 are mechanically (or physically) integrated. Specifically, the lead 14 is integrally coupled to the chip-mount substrate 24, the lead 16 to the wiring terminal 26a, and the lead 50 to the wiring terminal 26b, respectively. If the semiconductor chips 42a and 42b are MOS-FETs, the leads 14, 16, and 50, being terminals for external connection, correspond to a drain, a source, and a gate electrode terminal, respectively, as illustrated in the second embodiment. If the semiconductor chips 42a and 42b include IGBTs, the leads 14, 16, and 50 correspond to a collector, an emitter, and a gate electrode terminal, respectively. In the configuration of the semiconductor device 96, the chip-mount substrate 24 may be a die pad.

The chip unit 40 in the semiconductor device 96 may be sealed with resin. The semiconductor device 96 may also be housed in the case 60, as illustrated in the third embodiment. In this case, a case type semiconductor module including the semiconductor device 96 is configured. In such a case type semiconductor module, the leads 14, 16, and 50 may be bent such that a free end (one end) of each of the leads 14, 16, and 50 protrudes from the lid 72, instead of providing the gate electrode terminal 54 and the source electrode terminal 56 (see FIG. 7) and a terminal for external connection corresponding to a drain electrode terminal, illustrated in the third embodiment. The substrate for the semiconductor device 96 may be insulating or may also be the wiring substrate 58 similar to the third embodiment. If the semiconductor device 96 is mounted on the wiring substrate 58 similar to the third embodiment, the lead 14 is not necessary.

The semiconductor device 96 in FIG. 13 includes the chip unit 40 integrated with the leads 14, 16, and 50. Thus, if the chip-mount substrate 24 and the lead 14 integrated therewith are regarded as one chip-mount substrate, the wiring terminal 26a and the lead 16 integrated therewith as one first wiring terminal, and the wiring terminal 26b and the lead 50 integrated therewith as one second wiring terminal, then the chip unit 40 itself, which includes the chip-mount substrate and first and second wiring terminals including the parts corresponding to the leads 14, 16, and 50, may be a semiconductor device.

FIG. 13 illustrates another semiconductor device using the chip unit 40 described in the second embodiment; however, the chip units in the first, third, and fourth embodiments and the chip units in FIGS. 11 and 12 may configure semiconductor devices by directly connecting terminals for external connection, to the chip units. For example, the chip unit 18 in the first embodiment may configure a semiconductor device by integrating the conductive chip-mount substrate 24 with a terminal for external connection and also integrating the wiring terminal 26a as a first wiring terminal with a terminal for external connection. If the chip-mount substrate 80 is a flexible printed wiring substrate as in the fourth embodiment, a semiconductor device may be configured by directly connecting each of the wiring regions 86 and 88 on the insulating substrate 82 to a terminal for external connection and integrating the wiring terminal 26a with a terminal for external connection. If a chip-mount substrate and wiring terminals include portions corresponding to terminals for external connection as in the case of the semiconductor device 96 in FIG. 13, the chip unit itself may be a semiconductor a device.

What is claimed is:

1. A semiconductor device comprising:
a first semiconductor chip and a second semiconductor chip each including a first electrode and a second electrode opposite to each other in a predetermined direction;
a chip-mount substrate, the first and second semiconductor chips being mounted on the chip-mount substrate; and
a first wiring terminal, the second electrodes of the first and second semiconductor chips being connected to the first wiring terminal,
wherein the second semiconductor chip lies over the first semiconductor chip in the predetermined direction such that the second electrode of the first semiconductor chip and the second electrode of the second semiconductor chip face each other across the first wiring terminal, and
the chip-mount substrate is bent such that the first electrode of the first semiconductor chip is connected to the first electrode of the second semiconductor chip.

2. The semiconductor device according to claim 1, wherein each of the first and second semiconductor chips is a transistor or a diode.

3. The semiconductor device according to claim 1, further comprising a second wiring terminal, wherein
the first and second semiconductor chips are transistors,
each of the first and second semiconductor chips further includes a third electrode at the side of the second electrode, and
the second wiring terminal is connected to the third electrode of each of the first and second semiconductor chips.

4. The semiconductor device according to claim 1, wherein
the first and second semiconductor chips are transistors,
each of the first and second semiconductor chips further includes a third electrode at the side of the first electrode, and
the chip-mount substrate is a wiring substrate including a wiring region for the first electrodes of the first and second semiconductor chips and a wiring region for the third electrodes of the first and second semiconductor chips.

5. The semiconductor device according to claim 1, further comprising a die pad, the chip-mount substrate being mounted on the die pad.

6. The semiconductor device according to claim 1, wherein the chip-mount substrate comprises a flexible printed wiring substrate.

7. The semiconductor device according to claim 1, comprising a plurality of laminates each including:
the first semiconductor chip; the second semiconductor chip provided over the first semiconductor chip in the predetermined direction; and the wiring terminal provided between the second electrodes of the first and second semiconductor chips,
wherein the chip-mount substrate is bent such that the first electrodes of the first and second semiconductor chips in each laminate are connected with each other.

8. The semiconductor device according to claim 1, wherein a material of the first and second semiconductor chips comprises a wide band gap semiconductor.
